(19) United States
(12) Patent Application Publication
(10) Pub. No.: US 2026/0013034 A1
(43) Pub. Date: Jan. 8, 2026

(54) CIRCUIT BOARD, MANUFACTURING METHOD THEREOF, AND ELECTRONIC COMPONENT PACKAGE INCLUDING THE SAME

(71) Applicant: SAMSUNG ELECTRO-MECHANICS CO., LTD., Suwon-si (KR)

(72) Inventors: Jiho Yoon, Suwon-si (KR); Sanghoon Kim, Suwon-si (KR)

(73) Assignee: SAMSUNG ELECTRO-MECHANICS CO., LTD., Suwon-si (KR)

(21) Appl. No.: 19/012,671

(22) Filed: Jan. 7, 2025

(30) Foreign Application Priority Data
Jul. 2, 2024 (KR) 10-2024-0086809

(51) Int. Cl. H05K 1/02; H05K 1/14; H05K 3/00; H05K 3/46

(52) U.S. Cl. CPC H05K 1/0206; H05K 1/0207; H05K 1/144; H05K 3/007; H05K 3/4697; H05K 2201/09481; H05K 2201/096; H05K 2201/09618; H05K 2201/09827

(57) ABSTRACT

A disclosed circuit board may include an insulating layer including first and second surfaces opposing each other and having a cavity recessed from the first surface, and a heat dissipating portion partially positioned in the cavity. The insulating layer includes an upper surface portion configured to constitute the cavity and facing the second surface, and a side surface portion configured to surround the upper surface portion and to constitute the cavity. The heat dissipating portion is positioned to cover the side surface portion, and extends from the upper surface portion to the second surface through the insulating layer.

### CROSS-REFERENCE TO RELATED APPLICATION

This application claims priority to and the benefit of Korean Patent Application No. 10-2024-0086809, filed in the Korean Intellectual Property Office on Jul. 2, 2024, the entire contents of which are incorporated herein by reference.

### BACKGROUND

### (a) Field

The present disclosure relates to a circuit board, a manufacturing method for the same, and an electronic component package including the same.

### (b) Description of the Related Art

A circuit board is a circuit pattern formed with a conductive material such as copper on an insulating material. As electronic devices in the IT field, including mobile phones, have become miniaturized, a method of forming a cavity in a circuit board and mounting electronic components within the cavity has been proposed. Examples of electronic components mounted within the cavity include ICs, active devices, or passive devices.

As the depth of the circuit board cavity increases, more of the electronic components may be mounted within the cavity, and an overall thickness of a product packaging electronic components and circuit boards may be reduced. Additionally, the thickness of electronic components may be increased, thereby improving thermal characteristics.

However, as the depth of the cavity increases, there is a risk that warpage may occur in the circuit board due to the asymmetric structure. Accordingly, it is necessary to provide a heat dissipation structure with high thermal conductivity inside the cavity.

### SUMMARY

An aspect of the present disclosure attempts to provide a circuit board, a manufacturing method thereof, and an electronic component package including the same, capable of efficiently absorbing and dispersing heat generated from electronic components while securing a mounting space for electronic components.

An aspect of the present disclosure attempts to provide a circuit board, a manufacturing method thereof, and an electronic component package including the same, capable of capable of securing heat dissipation characteristics for electronic components of various thicknesses by adjusting a length of a heat dissipation portion to suit the purpose.

However, the problem to be solved by the embodiments of the present disclosure is not limited to the above-described problems, and can be variously extended within the scope of the technical spirit included in the present disclosure.

An embodiment provides a circuit board including: an insulating layer including first and second surfaces opposing each other and having a cavity recessed from the first surface, and a heat dissipating portion positioned in the cavity. The insulating layer includes an upper surface portion positioned in the cavity and facing the second surface, and a side surface portion surrounding the upper surface portion. The heat dissipating portion is positioned to cover the side surface portion, and extends from the upper surface portion to the second surface through the insulating layer.

The heat dissipating portion may include an extension configured to extend from the upper surface portion to an outside of the cavity and positioned on the side surface portion and the first surface, and the extension may include a first portion positioned in the cavity to cover the side surface portion, and a second portion connected to the first portion and positioned to protrude from a reference surface parallel to the first surface.

The heat dissipating portion may further include a first heat dissipation pattern positioned on the second surface.

The circuit board may further include at least one circuit layer buried in the insulating layer, and a first circuit layer connected to the at least one circuit layer and disposed around a first heat dissipation pattern on the second surface.

The heat dissipating portion may further include a first heat dissipation via electrode that extends through at least a portion of the insulating layer and connects the first heat dissipation pattern and the first portion.

The first heat dissipation via electrode may be positioned in a stacking direction such that a center line thereof coincides with the first portion.

The insulating layer may include a first insulating layer including the first surface on which the cavity is positioned, and a second insulating layer disposed on the first insulating layer and including the second surface on which the first heat dissipation pattern is positioned, and the heat dissipating portion may further include a second heat dissipation pattern positioned on a surface of the first insulating layer opposing the first surface, and a second heat dissipation via electrode positioned to connect the first heat dissipation pattern and the second heat dissipation pattern through the second insulating layer.

The circuit board may further include a third insulating layer stacked between the first insulating layer and the second insulating layer.

The circuit board may further include a circuit layer buried from the first surface and disposed around the first portion, and, in a thickness in a stacking direction, the first portion may have a greater thickness than the circuit layer.

The first portion and the second portion may have different planar areas.

The second portion may have a larger planar area than the first portion.

A portion of the second portion may be positioned on the first portion, and a remaining portion of the second portion may be positioned on the first insulating layer.

The first portion may extend along the side surface portion to surround the cavity.

The second portion may extend along an edge of the side surface portion.

An embodiment of the present disclosure provides an electronic component package including: a first circuit board having a cavity on a surface; a second circuit board connected to the first circuit board; and an electronic component mounted on a surface of the second circuit board and positioned in the cavity. The first circuit board may include an insulating layer including first and second surfaces opposing each other and having a cavity recessed from the first surface, and a heat dissipating portion positioned in the cavity. The insulating layer may include an upper surface portion positioned in the cavity and facing the second surface, and a side surface portion surrounding the upper surface portion. The heat dissipating portion may be positioned to cover the side surface portion, and may extend from the upper surface portion to the second surface through the insulating layer.

The heat dissipating portion may include an extension configured to extend from the upper surface portion to an outside of the cavity and positioned on the side surface portion and the first surface, and the extension may include a first portion positioned in the cavity to cover the side surface portion, and a second portion connected to the first portion and positioned to protrude from a reference surface parallel to the first surface.

The heat dissipation portion may further include a first heat dissipation pattern positioned on the second surface, and a first heat dissipation via electrode extending through at least a portion of the insulating layer and positioned to connect the first heat dissipation pattern and the first portion.

The first portion and the second portion may be positioned to surround the electronic component.

An embodiment provides a manufacturing method for a circuit board, including: forming a circuit layer and a first sacrificial layer; forming a first insulating layer to bury the circuit layer and the first sacrificial layer; forming a first heat dissipation via electrode to extend through the first insulating layer to be connected to an edge area of the first sacrificial layer; forming a first heat dissipation pattern on a surface of the first insulating layer to be connected to the first heat dissipation via electrode; forming a connector on another surface of the first insulating layer to be connected to the circuit layer; forming a second sacrificial layer on the first sacrificial layer; and forming a heat dissipating portion by etching a central area of the first sacrificial layer and a central area of the second sacrificial layer.

The forming of the second sacrificial layer may include forming the second sacrificial layer by forming a portion thereof on the first sacrificial layer and a remaining portion on the another surface of the first insulating layer.

In accordance with a circuit board, a manufacturing method therefor, and an electronic component package including the same according to an embodiment, by providing the heat dissipating portion in the cavity, it is possible to efficiently absorb and disperse heat generated from electronic components while securing mounting space for electronic components.

### BRIEF DESCRIPTION OF THE DRAWINGS

FIG. 1 illustrates a cross-sectional view of a circuit board according to an embodiment.

FIG. 2 illustrates a bottom view schematically showing a surface of the circuit board in FIG. 1.

FIG. 3 illustrates a cross-sectional view of a circuit board according to another embodiment.

FIG. 4 illustrates a cross-sectional view of a circuit board according to another embodiment.

FIG. 5 illustrates a cross-sectional view of a circuit board according to another embodiment.

FIG. 6 to FIG. 11 illustrate cross-sectional views showing a manufacturing method for a circuit board according to an embodiment.

FIG. 12 illustrates a schematic cross-sectional view of an electronic component package according to an embodiment.

### DETAILED DESCRIPTION

Hereinafter, various embodiment of the present disclosure will be described in detail so that a person of ordinary skill in the technical field to which the present disclosure belongs can easily implement it with reference to the accompanying drawings. The drawings and description are to be regarded as illustrative in nature and not restrictive. Like reference numerals designate like elements throughout the specification. In addition, some components in the accompanying drawings are exaggerated, omitted, or schematically illustrated, and the size of each component does not fully reflect the actual size.

The accompanying drawings are provided only in order to allow embodiments disclosed in the present specification to be easily understood and are not to be interpreted as limiting the spirit disclosed in the present specification, and it is to be understood that the present invention includes all modifications, equivalents, and substitutions without departing from the scope and spirit of the present invention.

Terms including ordinal numbers such as first, second, and the like will be used only to describe various components, and are not to be interpreted as limiting these components. The terms are only used to differentiate one component from other components.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

It will be further understood that terms “comprises/includes” or “have” used throughout the specification specify the presence of stated features, numerals, steps, operations, components, parts, or a combination thereof, but do not preclude the presence or addition of one or more other features, numerals, steps, operations, components, parts, or a combination thereof. Accordingly, unless explicitly described to the contrary, the word “comprise” and variations such as “comprises” or “comprising” will be understood to imply the inclusion of stated components but not the exclusion of any other components.

Further, throughout the specification, the phrase “in a plan view” means when an object portion is viewed from above, and the phrase “in a cross-sectional view” means when a cross-section taken by vertically cutting an object portion is viewed from the side.

Throughout this specification and the claims that follow, when it is described that an element is “coupled” to another element, the element may be “directly or physically coupled” to the other element or “indirectly or non-contactually coupled” to the other element through a third element.

In addition, throughout the specification, “connected” means that two or more components are not only directly connected, but two or more components may be connected indirectly through other components, physically connected as well as being electrically connected, or it may be referred to by different names depending on the location or function, but may mean integral.

Hereinafter, various embodiments and variations will be described in detail with reference to drawings.

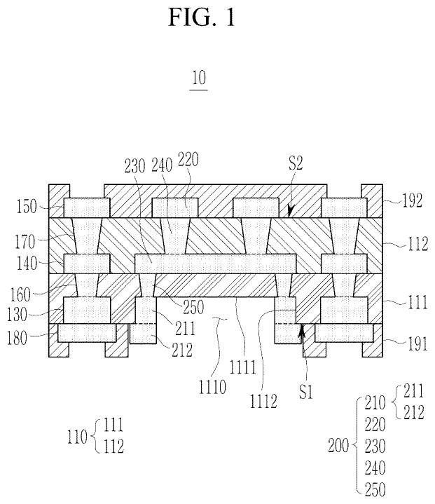

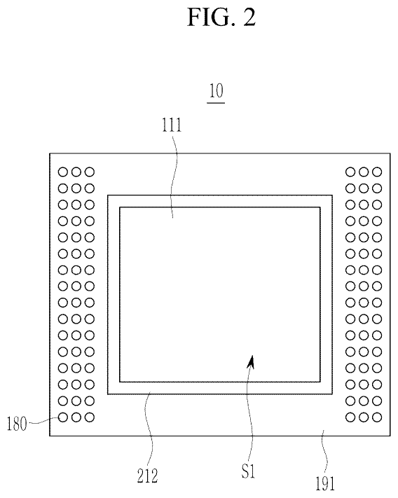

A circuit board according to an embodiment will be described with reference to FIG. 1 and FIG. 2. FIG. 1 illustrates a cross-sectional view of a circuit board according to an embodiment, and FIG. 2 illustrates a bottom view schematically showing a surface of the circuit board in FIG. 1.

Referring to FIG. 1, the circuit board 10 according to this embodiment may include an insulating layer 110 and a heat dissipating portion 200. The insulating layer 110 may include a first surface S1 and a second surface S2 that oppose each other. The insulating layer 110 may have a cavity 1110 recessed from the first surface S1. The heat dissipating portion 200 may include a portion positioned in the cavity 1110. The insulating layer 110 may include an upper surface portion 1111 positioned in the cavity 1110 and opposing the second surface S2, and a side surface portion 1112 surrounding the upper surface portion 1111. The heat dissipating portion 200 may be positioned to cover the side surface portion. The heat dissipating portion 200 may extend from the upper surface portion 1111 to the second surface S2 through the insulating layer 110.

The circuit board 10 according to an embodiment may include an insulating layer 110. A plurality of insulating layers 110 may be provided. As an example, the insulating layer 110 may include a first insulating layer 111 and a second insulating layer 112 disposed on the first insulating layer 111.

An insulating material may be used as a material for the insulating layer 110. The insulating material may include a thermosetting resin such as an epoxy resin, a thermoplastic resin such as polyimide, or these resins containing an inorganic filler such as silica and a reinforcing material such as glass fiber. For example, prepreg, resin coated copper foil (RCCF), etc. may be used as materials for each insulating layer 110, but the present disclosure is not limited thereto, and materials that do not contain reinforcing materials such as glass fiber, e.g., ajinomoto-build up film (ABF), etc. may be used. If necessary, a photosensitive insulating material such as photo image-able dielectric (PID) may be used as a material for each of the plurality of insulating layers.

The first insulating layer 111 may include a first surface S1. The cavity 1110 may be positioned on the first surface S1 of the first insulating layer 111. The first insulating layer 111 may bury at least one circuit layer. The first insulating layer 111 may have the cavity 1110 recessed from the first surface S1. The cavity 1110 may be recessed from the first surface S1 of the first insulating layer 111 to have a concave shape. The cavity 1110 may be formed through an etching process. Meanwhile, the circuit board 10, which is an interposer board, may be connected to a board on which electronic components are mounted. In this case, a sealant 23 (see FIG. 13) may be positioned inside the cavity 1110.

As an example, the first insulating layer 111 may include the first surface S1 on which the cavity 1110 is positioned. The second insulating layer 112 may include the second surface S2 on which a first heat dissipation pattern 220 is positioned.

The first insulating layer 111 may include the upper surface portion 1111 overlapping the cavity 1110 in a first direction and the side surface portion 1112 overlapping the cavity 1110 in a second direction perpendicular to the first direction. The upper surface portion 1111 and the side surface portion 1112 may form a cavity. The upper surface portion 1111 may oppose the second surface S2. The side surface portion 1112 may be shaped to surround the upper surface portion 1111.

The second insulating layer 112 may be stacked on a surface of the first insulating layer 111 in the first direction. The first direction may refer to a direction in which a plurality of insulating layers are stacked. The second insulating layer 112 may bury at least one circuit layer.

Referring to FIG. 1, one circuit layer is shown buried in the second insulating layer 112, but the present disclosure is not limited thereto, and more circuit layers than shown in the second insulating layer 112 may be buried, or no circuit layers may be buried.

The circuit board 10 according to an embodiment may include a plurality of circuit layers. At least some of the circuit layers may be positioned on the insulating layer 110. At least some of the remaining circuit layers may be buried in the insulating layer 110. Each of the circuit layers may transmit signals of the circuit board 10.

A metal material may be used as a material for the circuit layers 130, 140, and 150. The metal material may include copper (Cu), aluminum (Al), silver (Ag), tin (Sn), gold (Au), nickel (Ni), lead (Pb), titanium (Ti), or an alloy thereof. The circuit layers 130, 140, and 150 may perform various functions depending on a design thereof, such as ground pattern, power pattern, signal pattern, etc. These patterns may each have a form of a line, a plane, or a pad. For example, in the case of a circuit layer located in the outermost layer among the plurality of circuit layers 130, 140, and 150, it may function as a pad for connection to another board or component.

As an example, the circuit layers may include first to third circuit layers 130, 140, and 150.

The first circuit layer 130 may be disposed on the first surface S1 of the first insulating layer 111. The first circuit layer 130 may be buried in the first insulating layer 111. As an example, the first circuit layer 130 may include copper.

The second circuit layer 140 may be disposed on a surface of the first insulating layer 111. The second circuit layer 140 may be buried in the first insulating layer 111. As an example, the second circuit layer 140 may include copper.

The third circuit layer 150 may be disposed on the second insulating layer 112. The second insulating layer 112 may include a third surface that faces the second surface S2 of the second insulating layer. The third circuit layer 150 may be disposed on the second surface S2. The third circuit layer 150 may function as a pad for connection to other boards or components. As an example, the third circuit layer 150 may include copper.

Referring to FIG. 1, only the first to third circuit layers 130, 140, and 150 are shown, but the present disclosure is not limited thereto, and a greater number of circuit layers may be disposed than shown, or a smaller number of circuit layers may be disposed.

The circuit board 10 according to the present embodiment may include a plurality of via layers. A plurality of via layers may be arranged to electrically connect the first to third circuit layers 130, 140, and 150 to each other. A via electrode of each of the via layers may have a tapered shape where a width of a first surface is greater than a width of a second surface. A metal material may be used as a material for each of the via layers. The metal material may include copper (Cu), aluminum (Al), silver (Ag), tin (Sn), gold (Au), nickel (Ni), lead (Pb), titanium (Ti), or an alloy thereof.

The via layers may include signal vias, ground vias, power vias, etc. depending on a design thereof. The via electrodes of the via layers may each have a via hole completely filled with a metal material, or may be that a metallic material is formed along a wall of the via hole. Each of the via layers may be formed through a plating process, e.g., an additive process (AP), a semi AP (SAP), a modified SAP (MSAP), or a tenting (TT) process. Each of the via layers may include a seed layer that is an electroless plating layer and an electrolytic plating layer formed based on the seed layer.

As an example, the via layers may include first and second via layers 160 and 170.

The first via layer 160 may extend through the first insulating layer 111 to be connected to the first circuit layer 130 and the second circuit layer 140. Accordingly, the first via layer 160 may electrically connect the first circuit layer 130 and the second circuit layer 140 to each other.

The first via layer 160 may be disposed within the first insulating layer 111. The first via layer 160 may extend through the first insulating layer 111 to be connected to the first circuit layer 130 and the second circuit layer 140. Accordingly, the first via layer 160 may electrically connect the first circuit layer 130 and the second circuit layer 140 to each other.

The second via layer 170 may extend through the second insulating layer 112 to be connected to the second circuit layer 140 and the third circuit layer 150. Accordingly, the second via layer 170 may electrically connect the second circuit layer 140 and the third circuit layer 150 to each other.

The second via layer 170 may be disposed within the second insulating layer 112. The second via layer 170 may extend through the second insulating layer 112 to be connected to the second circuit layer 140 and the third circuit layer 150. Accordingly, the second via layer 170 may electrically connect the second circuit layer 140 and the third circuit layer 150 to each other.

Referring to FIG. 1, only the first and second via layers 160 and 170 are shown, but the present disclosure is not limited thereto, and more or fewer via layers may be disposed as needed.

The circuit board 10 according to an embodiment may include a heat dissipating portion 200. The heat dissipating portion 200 may include a side surface portion 1112 and an extension 210 positioned on the first surface S1. The extension 210 may extend from the upper surface portion 1111 to the outside of the cavity 1110. The extension 210 may include a first portion 211 and a second portion 212. The first portion 211 may be positioned in the cavity 1110 to cover the side surface portion 1112. The second portion 212 may be connected to the first portion 211, and may be arranged to protrude from a reference surface parallel to the first surface S1.

Referring to FIGS. 1 and 2, the first portion 211 may extend along the side surface portion 1112. The first portion 211 may be positioned to surround the cavity 1110. The first portion 211 and the second portion 212 may have different planar areas. The first circuit layer 130 may be disposed around the first portion 211. For example, the first circuit layer 130 may be buried from the first surface S1 to an inside of the first insulating layer 111. Herein, the first portion 211 and the first circuit layer 130 may be formed together in a manufacturing process. Accordingly, thicknesses of the first portion 211 and the first circuit layer 130 in the stacking direction may be similar. Similar thicknesses may include not only a case where the thicknesses are the same, but also a case where there is a difference in thicknesses, but a difference therebetween is within an error range, which may be caused by a processing error or a measurement error recognized by one ordinary skill in the art.

Referring to FIGS. 1 and 2, the second portion 212 may extend along an edge of the side surface portion 1112. The second portion 212 may be positioned to surround the cavity 1110. A portion of the second portion 212 may be positioned on the first portion 211, and a remaining portion of the second portion 212 may be positioned on the first insulating layer 111. A portion of the second portion 212 may overlap the first portion 211 in the stacking direction, and a remaining portion may not overlap the first portion 211 in the stacking direction. In other words, the second portion 212 may have a larger planar area than the first portion 211. The heat dissipating portion 200 may be positioned not only in an inner region of the cavity 1110 but also in an outer region of the first insulating layer 111. Accordingly, an area opposite to an area of an electronic component 22 to be mounted in the cavity 1110 may be increased. Through this, heat dissipation ability of the heat dissipating portion 200 may be improved.

The heat dissipating portion 200 of the circuit board 10 according to an embodiment may further include a first heat dissipation pattern 220, a second heat dissipation pattern 230, a first heat dissipation via electrode 240, and a second heat dissipation via electrode 250. The first heat dissipation pattern 220 may be positioned on the second surface S2. The second heat dissipation pattern 230 may be positioned on a surface of the first insulating layer 111 opposite to the first surface S1. The first heat dissipation via electrode 240 may be positioned to extend through at least a portion of the insulating layer 110, and may connect the first heat dissipation pattern 220 and the second heat dissipation pattern 230. The second heat dissipation via electrode 250 may be positioned to connect the first heat dissipation pattern 220 and the first portion 211 by extending through the first insulating layer 111.

The first heat dissipation pattern 220 may be positioned on the second insulating layer 112. The first heat dissipation pattern 220 may be electrically connected to the first portion 211. For example, the first heat dissipation pattern 220 may be connected to the first portion 211 through a heat dissipation via electrode. However, the present disclosure is not limited thereto, and another heat dissipation pattern is positioned between the first heat dissipation pattern 220 and the first portion 211, and the first heat dissipation pattern 220 may be connected to the first portion 211 through a plurality of heat dissipation via electrodes. For example, as shown in FIG. 1, the second heat dissipation pattern 230 may be positioned between the first heat dissipation pattern 220 and the first portion 211. Additionally, the first heat dissipation pattern 220 may be connected to the first portion 211 through the second heat dissipation via electrode 250.

The first heat dissipation via electrode 240 may extend through the second insulating layer 112 to be connected to the first heat dissipation pattern 220 and the second heat dissipation pattern 230. Accordingly, the first heat dissipation via electrode 240 may connect the first heat dissipation pattern 220 and the second heat dissipation pattern 230 to each other. The second via layer 170 may be disposed around the first heat dissipation via electrode 240.

The third circuit layer 150 may be disposed around the first heat dissipation pattern 220. The third circuit layer 150 may be disposed on the second surface S2. The first heat dissipation pattern 220 may be a dummy electrode or a heat dissipation via electrode. As an example, the first heat dissipation pattern 220 may not perform a signal transmission function, but may function to transmit heat generated in the circuit board 10 of the embodiment. However, the present disclosure is not limited to thereto, and the first heat dissipation pattern 220 may function to transmit heat generated from the circuit board 10 while performing the signal transmission function.

The second heat dissipation pattern 230 may be positioned on the first insulating layer 111. The second heat dissipation pattern 230 may be electrically connected to the first portion 211 and the first heat dissipation pattern 220. For example, the second heat dissipation pattern 230 may be connected to the first portion 211 through the second heat dissipation via electrode 250. However, the present disclosure is not limited thereto, and another heat dissipation pattern is positioned between the second heat dissipation pattern 230 and the first portion 211, and the second heat dissipation pattern 230 may be connected to the first portion 211 through a plurality of heat dissipation via electrodes. Meanwhile, the second heat dissipation pattern 230 may be connected to the first heat dissipation pattern 220 through the first heat dissipation via electrode 240. However, the present disclosure is not limited thereto, and another heat dissipation pattern is positioned between the second heat dissipation pattern 230 and the first heat dissipation pattern 220, and the second heat dissipation pattern 230 may be connected to the first heat dissipation pattern 220 through a plurality of heat dissipation via electrodes.

The second heat dissipation via electrode 250 may be connected to the first heat dissipation pattern 230 and the first portion 211 by extending through the first insulating layer 111. Accordingly, the second heat dissipation via electrode 250 may connect the second heat dissipation pattern 230 and the first portion 211 to each other. The first via layer 160 may be disposed around the second heat dissipation via electrode 250.

The second circuit layer 140 may be disposed around the second heat dissipation pattern 230. The second circuit layer 140 may be disposed on a surface of the insulating layer 110 opposite to the first surface S1. The second heat dissipation pattern 230 may be a dummy electrode or a heat dissipation via electrode. As an example, the second heat dissipation pattern 230 may not perform a signal transmission function, but may function to transmit heat generated in the circuit board 10 of the embodiment. However, the present disclosure is not limited to thereto, and the second heat dissipation pattern 230 may function to transmit heat generated from the circuit board 10 while performing the signal transmission function.

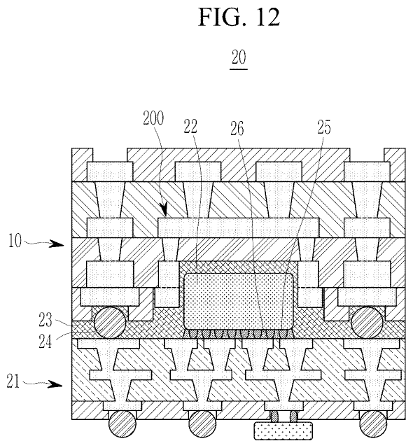

The second heat dissipation pattern 230 may receive heat from the first portion 211 through the second heat dissipation via electrode 250. The first heat dissipation pattern 220 may receive heat from the second heat dissipation pattern 230 through the first heat dissipation via electrode 240. Accordingly, the first heat dissipation pattern 220 may transfer heat generated from the electronic component 22 (see FIG. 12) positioned in the cavity 1110 to the outside of the circuit board 10, and a heat dissipation characteristic of the circuit board 10 may be improved.

The first portion 211 and the second portion 212 may have a shape surrounding the cavity. Accordingly, the heat generated from the electronic component 22 (see FIG. 12) positioned in the cavity 1110 may be transferred to the outside of the circuit board 10. In addition, the heat dissipation characteristics of the circuit board 10 may be improved by securing an area facing the electronic component 22.

As the first heat dissipation pattern 220 and the second heat dissipation pattern 230 are connected to the first portion 211, the heat generated in the circuit board 10 may be distributed upward. In addition, the heat generated in the circuit board 10 may be distributed downward by providing the second portion 212 connected to the first portion 211.

A metal material may be used as a material for the heat dissipating portion 200. For example, the metal material may include copper (Cu), aluminum (Al), silver (Ag), tin (Sn), gold (Au), nickel (Ni), lead (Pb), titanium (Ti), or an alloy thereof.

A connector 180 may be positioned on the first surface S1 of the insulating layer 110. The connector 180 may function as a pad for connection to other boards or components. As an example, the connector 180 may include copper. Herein, the connector 180 and the second portion 212 may be formed together in a manufacturing process. Accordingly, thicknesses of the connector 180 and the second portion 212 in the stacking direction may be similar. Similar thicknesses may include not only a case where the thicknesses are the same, but also a case where there is a difference in thicknesses, but a difference therebetween is within an error range, which may be caused by a processing error or a measurement error recognized by one ordinary skill in the art.

A first solder resist layer 191 may be positioned on the first surface S1 to cover a portion of the connector 180 to prevent unnecessary short circuits. The first solder resist layer 191 may be disposed to expose at least a portion of the connector 180. The first solder resist layer 191 may include a photosensitive resin material.

A second solder resist layer 192 may be positioned on the second surface S2 to cover a portion of the third circuit layer 150 to prevent unnecessary short circuits. The second solder resist layer 192 may be disposed to expose at least a portion of the third circuit layer 150. The second solder resist layer 192 may include a photosensitive resin material.

According to a circuit board according to an embodiment, as the heat dissipating portion covering the side surface is positioned within the cavity where the electronic components are accommodated, a space for mounting electronic components may be secured, and heat generated from electronic components may be efficiently absorbed and dispersed.

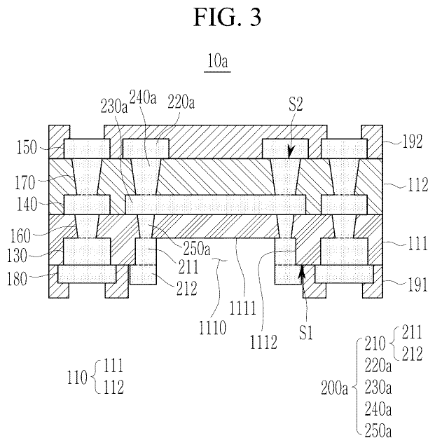

Hereinafter, a circuit board 10a according to another embodiment will be described with reference to FIG. 3. FIG. 3 illustrates a cross-sectional view of a circuit board according to another embodiment.

Referring to FIG. 3, the circuit board 10a according to another embodiment is similar to the circuit board 10 according to the embodiment described with reference to FIGS. 1 and 2 except for a shape of the heat dissipating portion 200a. Below, detailed descriptions of the same components will be omitted.

Referring to FIG. 3, in another embodiment, a first heat dissipation via electrode 240a may be positioned in the stacking direction such that a center line thereof coincides with that of the first portion 211. A second heat dissipation via electrode 250a may be positioned in the stacking direction such that a center line thereof coincides with that of the first portion 211. The first portion 211, the second heat dissipation via electrode 250a, and the first heat dissipation via electrode 240a may be arranged according to a first direction. The first portion 211, the second heat dissipation via electrode 250a, and the first heat dissipation via electrode 240a may be arranged in a line in a direction parallel to the first direction.

As described above, as the heat dissipation via electrode is arranged in a straight line with the first portion 211, heat generated in a lower portion of the circuit board 10 may be quickly transferred to an upper portion of the board. Accordingly, heat may be efficiently distributed to the outside of the circuit board.

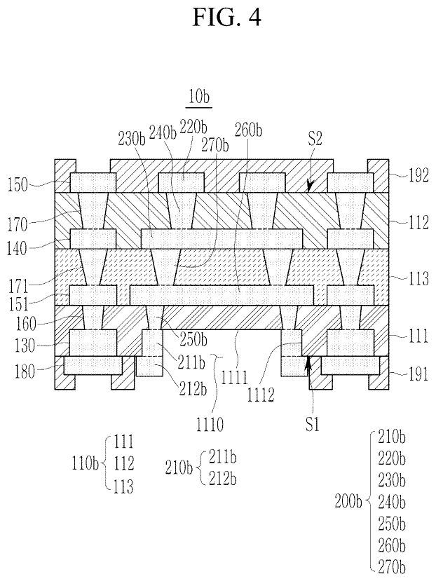

Hereinafter, a circuit board according to another embodiment will be described with reference to FIG. 4. FIG. 4 illustrates a cross-sectional view of a circuit board according to another embodiment.

Referring to FIG. 4, the circuit board 10b according to another embodiment is similar to the circuit board 10 according to the embodiment described with reference to FIGS. 1 and 2 except for a structure of the insulating layer 110b and a structure of the heat dissipating portion 200b. Below, detailed descriptions of the same components will be omitted.

Referring to FIG. 4, the insulating layer 110b according to another embodiment may further include a third insulating layer 113 disposed between the first insulating layer 111 and the second insulating layer 112. A third insulating layer 113 may be disposed between the first insulating layer 111 and second insulating layer 112. The third insulating layer 113 may be stacked on the first insulating layer 111 in the first direction.

In FIG. 4, the third insulating layer 113 is shown as being formed of one layer, but the present disclosure is not limited thereto, and may be formed of more layers than shown. In other words, the third insulating layer 113 may include at least one layer.

At least one circuit layer may be buried in the second insulating layer 112. As an example, the third circuit layer 150 may be buried in the second insulating layer 112. The third circuit layer 150 may be disposed on a surface of the first insulating layer 111 opposite to the first surface S1 of the insulating layer 110b. As an example, the third circuit layer 150 may include copper.

Referring to FIG. 4, one circuit layer is shown buried in the second insulating layer 112, but the present disclosure is not limited thereto, and more circuit layers than shown in the second insulating layer 112 may be buried, or no circuit layers may be buried.

The circuit board 10b according to another embodiment may further include a third via layer 171 and a third heat dissipation via electrode 270b.

The third via layer 171 may be disposed within the third insulating layer 113. The third via layer 171 may extend through the third insulating layer 113 to be connected to the second circuit layer 140 and the third circuit layer 150. Accordingly, the third via layer 171 may electrically connect the second circuit layer 140 and the third circuit layer 150 to each other.

In FIG. 4, the third insulating layer 113 is shown as including one via layer, but the present disclosure is not limited thereto, and may include more via layers than shown or may not include a via layer.

The circuit board 10 according to another embodiment may include a heat dissipating portion 200b. The heat dissipating portion 200b may include a first portion 211b and a second portion 212b. The first portion 211b may be positioned in the cavity 1110 to cover the side surface portion 1112. The second portion 212b may be connected to the first portion 211b, and may be arranged to protrude from a reference surface parallel to the first surface S1.

Referring to FIGS. 1 and 2, the first portion 211b may extend along the side surface portion 1112. The first portion 211b may be positioned to surround the cavity 1110. The first portion 211b and the second portion 212b may have different planar areas. The first circuit layer 130 may be disposed around the first portion 211b. For example, the first circuit layer 130 may be buried from the first surface S1 to an inside of the first insulating layer 111. Herein, the first portion 211b and the first circuit layer 130 may be formed together in a manufacturing process. Accordingly, thicknesses of the first portion 211b and the first circuit layer 130 in the stacking direction may be similar. Similar thicknesses may include not only a case where the thicknesses are the same, but also a case where there is a difference in thicknesses, but a difference therebetween is within an error range, which may be caused by a processing error or a measurement error recognized by one ordinary skill in the art.

Referring to FIG. 4, the second portion 212b may extend along an edge of the side surface portion 1112. The second portion 212b may be positioned to surround the cavity 1110. A portion of the second portion 212b may be positioned on the first portion 211b, and a remaining portion of the second portion 212b may be positioned on the first insulating layer 111. A portion of the second portion 212b may overlap the first portion 211b in the stacking direction, and a remaining portion may not overlap the first portion 211b in the stacking direction. In other words, the second portion 212b may have a larger planar area than the first portion 211b. The heat dissipating portion 200b may be positioned not only in an inner region of the cavity 1110 but also in an outer region of the first insulating layer 111. Accordingly, an area opposite to an area of an electronic component 22 to be mounted in the cavity 1110 may be increased. Through this, heat dissipation ability of the heat dissipating portion 200b may be improved.

The heat dissipating portion 200b of the circuit board 10b according to an embodiment may further include a first heat dissipation pattern 220b, a second heat dissipation pattern 230b, a third heat dissipation pattern 260b, a first heat dissipation via electrode 240b, a second heat dissipation via electrode 250b, and a third heat dissipation via electrode 270b. The first heat dissipation pattern 220b may be positioned on the second surface S2. The second heat dissipation pattern 230b may be positioned on a surface of the third insulating layer 110b opposite to the second surface S2. The third heat dissipation pattern 260b may be positioned other surface of the third insulating layer 110b opposite to the first surface S1. The first heat dissipation via electrode 240b may be positioned to extend through at least a portion of the insulating layer 110b, and may connect the first heat dissipation pattern 220b and the second first portion 211b. The second heat dissipation via electrode 250b may be positioned to connect the third heat dissipation pattern 260b and the first portion 211b by extending through the first insulating layer 111. The third heat dissipation via electrode 270b may be positioned to connect the second heat dissipation pattern 230b and the third heat dissipation pattern 260b by extending through the third insulating layer 110b.

The first heat dissipation pattern 220b may be positioned on the second insulating layer 112. The first heat dissipation pattern 220b may be electrically connected to the first portion 211b. For example, the first heat dissipation pattern 220b may be connected to the first portion 211b through a plurality of heat dissipation via electrodes. For example, as shown in FIG. 4, the second heat dissipation pattern 230b and the third heat dissipation pattern 260b may be positioned between the first heat dissipation pattern 220b and the first portion 211b. In addition, the second heat dissipation pattern 230b may be connected to the first heat dissipation pattern 220b through the first heat dissipation via electrode 240b. The third heat dissipation pattern 260b may be connected to the second heat dissipation pattern 230b through the third heat dissipation via electrode 270b.

The first heat dissipation via electrode 240b may extend through the second insulating layer 112 to be connected to the first heat dissipation pattern 220b and the second heat dissipation pattern 230b. Accordingly, the first heat dissipation via electrode 240b may connect the first heat dissipation pattern 220b and the second heat dissipation pattern 230b to each other. The second via layer 170 may be disposed around the first heat dissipation via electrode 240b.

The third circuit layer 150 may be disposed around the first heat dissipation pattern 220b. The third circuit layer 150 may be disposed on the second surface S2. The first heat dissipation pattern 220b may be a dummy electrode or a heat dissipation via electrode. As an example, the first heat dissipation pattern 220b may not perform a signal transmission function, but may function to transmit heat generated in the circuit board 10b of the embodiment. However, the present disclosure is not limited to thereto, and the first heat dissipation pattern 220b may function to transmit heat generated from the circuit board 10b while performing the signal transmission function.

The second heat dissipation pattern 230b may be positioned on the third insulating layer 110b. The second heat dissipation pattern 230b may be electrically connected to the first heat dissipation pattern 220b and the third heat dissipation pattern 260b. The second heat dissipation pattern 230b may be connected to the first portion 211b through the third heat dissipation via electrode 270b and the second heat dissipation via electrode 250b. Meanwhile, the second heat dissipation pattern 230b may be connected to the first heat dissipation pattern 220b through the first heat dissipation via electrode 240b. However, the present disclosure is not limited thereto, and another heat dissipation pattern is positioned between the second heat dissipation pattern 230b and the first heat dissipation pattern 220b, and the second heat dissipation pattern 230b may be connected to the first heat dissipation pattern 220b through a plurality of heat dissipation via electrodes.

The second heat dissipation via electrode 250b may extend through the first insulating layer 111 to be connected to the first portion 211b and the third heat dissipation pattern 260b. Accordingly, the second heat dissipation via electrode 250b may connect the first portion 211b and the third heat dissipation pattern 260b to each other. The first via layer 160 may be disposed around the second heat dissipation via electrode 250b.

The second circuit layer 140 may be disposed around the second heat dissipation pattern 230b. The second circuit layer 140 may be disposed on a surface of the third insulating layer 110b opposite to the second surface S2 of the insulating layer 110b. The second heat dissipation pattern 230b may be a dummy electrode or a heat dissipation via electrode. As an example, the second heat dissipation pattern 230b may not perform a signal transmission function, but may function to transmit heat generated in the circuit board 10b of the embodiment. However, the present disclosure is not limited to thereto, and the second heat dissipation pattern 230b may function to transmit heat generated from the circuit board 10b while performing the signal transmission function.

The third heat dissipation pattern 260b may be positioned on the first insulating layer 111. The third heat dissipation pattern 260b may be electrically connected to the second heat dissipation pattern 230b and the first portion 211b. The third heat dissipation pattern 260b may be connected to the first portion 211b through the third heat dissipation via electrode 250b. Meanwhile, the third heat dissipation pattern 260b may be connected to the second heat dissipation pattern 230b through the third heat dissipation via electrode 270b.

The third heat dissipation via electrode 270b may be connected to the second heat dissipation pattern 230b and the third heat dissipation pattern 260b by extending through the third insulating layer 110b. Accordingly, the second heat dissipation via electrode 250b may connect the second heat dissipation pattern 230b and the third heat dissipation pattern 260b to each other. The third via layer 171 may be disposed around the second heat dissipation via electrode 250b.

The third circuit layer 150 may be disposed around the third heat dissipation pattern 260b. The third circuit layer 150 may be disposed on a surface of the third insulating layer 110b opposite to the first surface S1 of the insulating layer 110b. The third heat dissipation pattern 260b may be a dummy electrode or a heat dissipation via electrode. As an example, the third heat dissipation pattern 260b may not perform a signal transmission function, but may function to transmit heat generated in the circuit board 10b of another embodiment. However, the present disclosure is not limited to thereto, and the third heat dissipation pattern 260b may function to transmit heat generated from the circuit board 10b while performing the signal transmission function.

The first heat dissipation pattern 220b may be connected to the second heat dissipation pattern 230b through the first heat dissipation via electrode 240b. The first heat dissipation via electrode 240b may connect the first heat dissipation pattern 220b and the second heat dissipation pattern 230b to each other. The first heat dissipation via electrode 240b may function to transfer heat generated from the circuit board 10b of the embodiment. The first heat dissipation pattern 220b may receive heat from the second heat dissipation pattern 230b through the first heat dissipation via electrode 240b. Accordingly, the first heat dissipation pattern 220b may transfer heat generated from the electronic component 22 positioned in the cavity 1110 to the outside of the circuit board 10b, and a heat dissipation characteristic of the circuit board 10 may be improved.

The second dissipation pattern 230b may be connected to the first portion 211b through the third heat dissipation via electrode 250b. The second heat dissipation via electrode 250b may connect the second heat dissipation pattern 230b and the first portion 211b to each other. The second heat dissipation via electrode 250b may function to transfer heat generated in the circuit board 10b of the embodiment. The second heat dissipation pattern 230b may receive heat from the first portion 211b through the second heat dissipation via electrode 250b. Accordingly, the second heat dissipation pattern 230b may transfer heat generated from the electronic component 22 positioned in the cavity 1110 to the outside of the circuit board 10b, and a heat dissipation characteristic of the circuit board 10 may be improved.

The third dissipation pattern 230b may be connected to the first portion 211b through the third heat dissipation via electrode 260b. The second heat dissipation pattern 230b may receive heat from the first portion 211b through the first heat dissipation via electrode 260b. Accordingly, the second heat dissipation pattern 230b may transfer heat generated from the electronic component 22 positioned in the cavity 1110 to the outside of the circuit board 10, and a heat dissipation characteristic of the circuit board 10b may be improved.

The third heat dissipation pattern 260b may receive heat from the first portion 211b through the second heat dissipation via electrode 250b. The second heat dissipation pattern 230b may receive heat from the third heat dissipation pattern 260b through the third heat dissipation via electrode 270b. The first heat dissipation pattern 220b may receive heat from the second heat dissipation pattern 230b through the first heat dissipation via electrode 240b. Accordingly, the first heat dissipation pattern 220b may transfer heat generated from the electronic component 22 (see FIG. 12) positioned in the cavity 1110 to the outside of the circuit board 10b, and a heat dissipation characteristic of the circuit board 10b may be improved.

The first portion 211b and the second portion 212b may have a shape surrounding the cavity. Accordingly, the heat generated from the electronic component 22 (see FIG. 12) positioned in the cavity 1110 may be transferred to the outside of the circuit board 10b. In addition, the heat dissipation characteristics of the circuit board 10b may be improved by securing an area facing the electronic component 22.

As the first heat dissipation pattern 220b, the second heat dissipation pattern 230b, and the third heat dissipation pattern 260b are connected to the first portion 211b, the heat generated in circuit board 10 may be distributed upward. In addition, the heat generated in the circuit board 10 may be distributed downward by providing the second portion 212b connected to the first portion 211b.

As described above, as the heat dissipating portion is formed to extend from the cavity positioned on the first surface to the second surface, heat generated on a surface of the insulating layer may be transferred to other surface regardless of a thickness of the insulating layer. Additionally, the heat dissipation characteristic of the circuit board 10 may be secured accordingly.

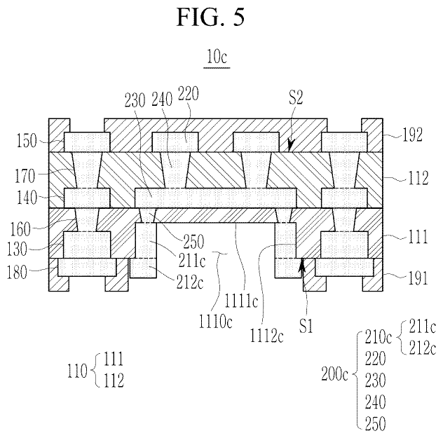

Hereinafter, a circuit board according to another embodiment will be described with reference to FIG. 5. FIG. 5 illustrates a cross-sectional view of a circuit board according to another embodiment.

Referring to FIG. 5, the circuit board 10c according to another embodiment is similar to the circuit board 10 according to the embodiment described with reference to FIGS. 1 and 2 except for a shape of the first portion 211c and a shape of the cavity 1110c. Below, detailed descriptions of the same components will be omitted.

Referring to FIG. 5, in the circuit board 10c according to another embodiment, a depth at which a cavity 1110c is depressed from the first surface S1 may vary depending on the purpose. For example, an electronic component disposed in the cavity 1110c may be thick. In this case, the cavity 1110c may be formed deeper than the cavity 1110 of the circuit board 10c according to the embodiment described with reference to FIGS. 1 and 2.

Accordingly, a thickness of a side surface portion 1112c constituting the cavity 1110c may increase. In addition, a thickness of a first portion 211c positioned to cover the side surface portion 1112c may be greater than that of the cavity 1110c of the circuit board 10 according to the embodiment described with reference to FIGS. 1 and 2.

In a manufacturing process, the first portion 211c may be formed through a separate process to increase a depth of the cavity 1110 and a thickness of the first portion 211c in addition to a process in which it is formed together with the first circuit layer 130. For example, a plating layer may be formed to form a portion of the first portion 211c together with the first circuit layer 130, and on this plating layer, another separate plating layer may be formed to form a remaining portion of the first portion 211c. Herein, some areas of the plating layers may be etched to form the cavity 1110c and the first portion 211c according to another embodiment. Accordingly, in terms of a thickness according to the first direction, the first portion 211c may have a thickness greater than that of the first circuit layer 130. In other words, in terms of a height measured in the first direction with respect to the first surface S1, a height of the first portion 211c may be higher than a height of the first circuit layer 130.

As described above, in accordance with a circuit board according to another embodiment, the length of the first portion 211c may be adjusted to suit the purpose, so that the heat dissipating portion can be applied to electronic components of various thicknesses.

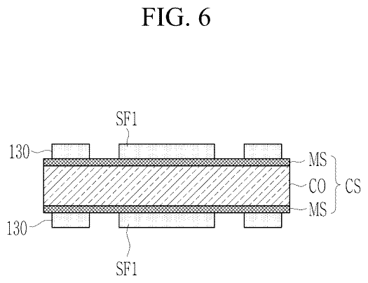

A manufacturing method for a display device according to an embodiment will now be described with reference to FIG. 6 to FIG. 11. FIG. 6 to FIG. 11 illustrate cross-sectional views showing a manufacturing method for a circuit board according to an embodiment.

Referring to FIG. 6, the first circuit layer 130 may be disposed on a carrier substrate CS including a core portion CO and a thin metal layer MS stacked on opposite sides of the core portion CO. Herein, a first sacrificial layer SF1 may be formed at a position where the cavity 1110 is to be formed.

The first circuit layer 130 and the first sacrificial layer SF1 may each be formed through a plating process. The first circuit layer 130 and the first sacrificial layer SF1 may be formed using any of semi additive process (SAP), modified semi additive process (MSAP), tenting (TT) or subtractive method. However, the present disclosure is not limited thereto, and any method capable of forming a pattern on a circuit board may be used without limitation.

The first circuit layer 130 and the first sacrificial layer SF1 may each include an electroless plating layer (or chemical copper) as a seed layer and an electrolytic plating layer (or electrolytic copper) as a plating layer, but the present disclosure is not limited thereto. To form the electroless plating layer, a sputtering layer may be used instead of the chemical copper. For example, the first circuit layer 130 and the first sacrificial layer SF1 may each be formed by forming a seed layer on a copper foil by electroless plating, forming a photoresist on the seed layer, patterning the photoresist through exposure and development processes, filling the patterned area with electroplating, and peeling off the photoresist. As required, the seed layer may not include the copper foil or may further include the copper foil.

The first sacrificial layer SF1 may be formed together with the first circuit layer 130. The first sacrificial layer SF1 may be made of a same material as the first circuit layer 130. The first sacrificial layer SF1 may have a thickness similar to that of the first circuit layer 130. Similar thicknesses may include not only a case where the thicknesses are the same, but also a case where there is a difference in thicknesses, but a difference therebetween is within an error range, which may be caused by a processing error or a measurement error recognized by one ordinary skill in the art. The thickness of the first sacrificial layer SF1 may correspond to a depth of the cavity 1110 formed later.

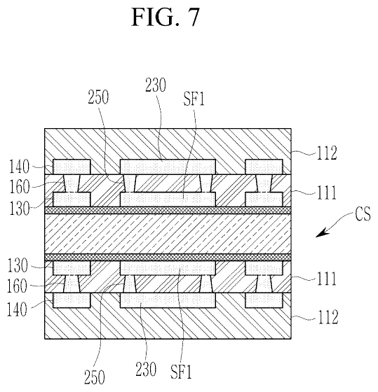

Referring to FIG. 7, the first insulating layer 111 may be formed to bury the first circuit layer 130 and the first sacrificial layer SF1. The first insulating layer 111 may be formed by using a material such as such as prepreg (PPG), Ajinomoto build-up film (ABF), resin coated copper foil (RCC), etc.

The second circuit layer 140 and the second heat dissipation pattern 230 may be disposed on the first insulating layer 111. The second circuit layer 140 and the second heat dissipation pattern 230 may each be formed through a plating process. The second circuit layer 140 and the second heat dissipation pattern 230 may be formed using any of semi additive process (SAP), modified semi additive process (MSAP), tenting (TT) or subtractive method. However, the present disclosure is not limited thereto, and any method capable of forming a pattern on a circuit board may be used without limitation.

The second circuit layer 140 and the second heat dissipation pattern 230 may each include an electroless plating layer (or chemical copper) as a seed layer and an electrolytic plating layer (or electrolytic copper) as a plating layer, but the present disclosure is not limited thereto. To form the electroless plating layer, a sputtering layer may be used instead of the chemical copper. For example, the second circuit layer 140 and the second heat dissipation pattern 230 may each be formed by forming a seed layer on a copper foil by electroless plating, forming a photoresist on the seed layer, patterning the photoresist through exposure and development processes, filling the patterned area with electroplating, and peeling off the photoresist. As required, the seed layer may not include the copper foil or may further include the copper foil.

The second heat dissipation pattern 230 may be formed together with the second circuit layer 140. The second heat dissipation pattern 230 may be made of a same material as the second circuit layer 140. The second heat dissipation pattern 230 may have a thickness similar to that of the second circuit layer 140. Similar thicknesses may include not only a case where the thicknesses are the same, but also a case where there is a difference in thicknesses, but a difference therebetween is within an error range, which may be caused by a processing error or a measurement error recognized by one ordinary skill in the art.

Meanwhile, the first via layer 160 may be formed by extending through at least a portion of the first insulating layer 111. The first via layer 160 may include at least one via electrode. The first via layer 160 may be formed to contact the first circuit layer 130 and the second circuit layer 140. In other words, the first via layer 160 may be formed to connect the first circuit layer 130 and the second circuit layer 140. The first via layer 160 may be formed by laser processing, mechanical drilling, etc. For example, a via extending through at least a portion of the first insulating layer 111 may be formed using a laser or the like. In addition, the first via layer 160 may be formed by filling a via with a conductive material.

The second heat dissipation via electrode 250 may be formed by extending through another portion of the first insulating layer 111. A second heat dissipation via electrode 250 may be formed to contact the first sacrificial layer SF1 and the second heat dissipation pattern 230. In other words, the second heat dissipation via electrode 250 may be formed to connect the first sacrificial layer SF1 and the first heat dissipation pattern 220. The second heat dissipation via electrode 250 may be formed to be connected to an edge region of the first sacrificial layer SF1. The second heat dissipation via electrode 250 may be formed such that a first end is in contact with the first sacrificial layer SF1. The second heat dissipation via electrode 250 may be formed by laser processing, mechanical drilling, etc. For example, a via extending through at least a portion of the first insulating layer 111 may be formed using a laser or the like. In addition, the second heat dissipation via electrode 250 may be formed by filling a via with a conductive material.

Referring to FIG. 7, the second insulating layer 112 may be disposed on the first insulating layer 111 such that the second heat dissipation pattern 230 and the second circuit layer 140 are buried. The second insulating layer 112 may be formed by using a material such as such as prepreg (PPG), Ajinomoto build-up film (ABF), resin coated copper foil (RCC), etc. The insulating layer 110 may be formed by forming the first insulating layer 111 and the second insulating layer 112.

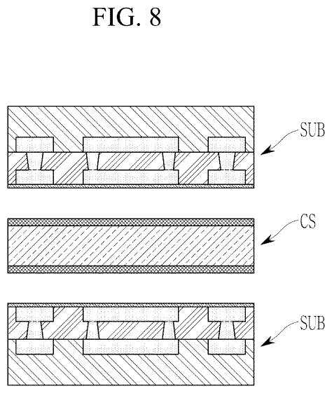

Referring to FIG. 8, the substrate SUB may be separated from opposite sides of the carrier substrate CS.

Hereinafter, one substrate portion SUB separated from the carrier substrate CS will be described.

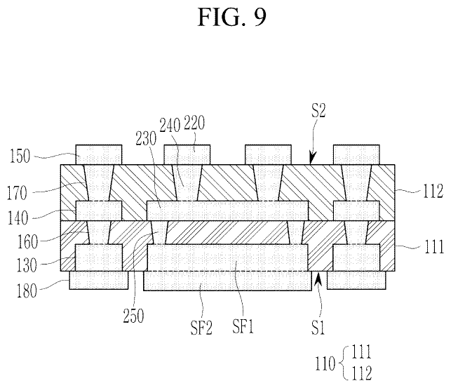

Referring to FIG. 9, the third circuit layer 150 and the first heat dissipation pattern 220 may be positioned on the second insulating layer 112. The third circuit layer 150 and the first heat dissipation pattern 220 may each be formed through a plating process. The third circuit layer 150 and the first heat dissipation pattern 220 may be formed using any of semi additive process (SAP), modified semi additive process (MSAP), tenting (TT) or subtractive method. However, the present disclosure is not limited thereto, and any method capable of forming a pattern on a circuit board may be used without limitation.

The third circuit layer 150 and the first heat dissipation pattern 220 may each include an electroless plating layer (or chemical copper) as a seed layer and an electrolytic plating layer (or electrolytic copper) as a plating layer, but the present disclosure is not limited thereto. To form the electroless plating layer, a sputtering layer may be used instead of the chemical copper. For example, the third circuit layer 150 and the first heat dissipation pattern 220 may each be formed by forming a seed layer on a copper foil by electroless plating, forming a photoresist on the seed layer, patterning the photoresist through exposure and development processes, filling the patterned area with electroplating, and peeling off the photoresist. As required, the seed layer may not include the copper foil or may further include the copper foil.

The first heat dissipation pattern 220 may be formed together with the third circuit layer 150. The first heat dissipation pattern 220 may be made of a same material as the third circuit layer 150. The first heat dissipation pattern 220 may have a thickness similar to that of the third circuit layer 150. Similar thicknesses may include not only a case where the thicknesses are the same, but also a case where there is a difference in thicknesses, but a difference therebetween is within an error range.

Meanwhile, the second via layer 170 may be formed by extending through at least a portion of the second insulating layer 112. The second via layer 170 may include at least one via electrode. The first via layer 160 may be formed to contact the second circuit layer 140 and the third circuit layer 150. In other words, the second via layer 170 may be formed to connect the second circuit layer 140 and the third circuit layer 150. The second via layer 170 may be formed by laser processing, mechanical drilling, etc. For example, a via extending through at least a portion of the second insulating layer 112 may be formed using a laser or the like. In addition, the second via layer 170 may be formed by filling a via with a conductive material.

The first heat dissipation via electrode 240 may be formed by extending through another portion of the second insulating layer 112. The first heat dissipation via electrode 240 may be formed to contact the first heat dissipation pattern 220 and the second heat dissipation pattern 230. In other words, the first heat dissipation via electrode 240 may be formed to connect the first heat dissipation pattern 220 and the second heat dissipation pattern 230. The first heat dissipation via electrode 240 may be formed by laser processing, mechanical drilling, etc. For example, a via extending through at least a portion of the second insulating layer 112 may be formed using a laser or the like, and the first heat dissipation via electrode 240 may be formed by filling the via with a conductive material.

Referring to FIG. 9, the connector 180 and the second sacrificial layer SF2 may be disposed on the first insulating layer 111. A portion of the second sacrificial layer SF2 may be positioned on the first sacrificial layer SF1, and a remaining portion may be positioned on a surface of the first insulating layer 111. The first surface of the first insulating layer 111 may correspond to the first surface S1 of the insulating layer 110.

The connector 180 and the second sacrificial layer SF2 may each be formed through a plating process. The connector 180 and the second sacrificial layer SF2 may be formed using any of semi additive process (SAP), modified semi additive process (MSAP), tenting (TT) or subtractive method. However, the present disclosure is not limited thereto, and any method capable of forming a pattern on a circuit board may be used without limitation.

The connector 180 and the second sacrificial layer SF2 may each include an electroless plating layer (or chemical copper) as a seed layer and an electrolytic plating layer (or electrolytic copper) as a plating layer, but the present disclosure is not limited thereto. To form the electroless plating layer, a sputtering layer may be used instead of the chemical copper. For example, the connector 180 and the second sacrificial layer SF2 may each be formed by forming a seed layer on a copper foil by electroless plating, forming a photoresist on the seed layer, patterning the photoresist through exposure and development processes, filling the patterned area with electroplating, and peeling off the photoresist. As required, the seed layer may not include the copper foil or may further include the copper foil.

The connector 180 may be formed together with the second sacrificial layer SF2. The connector 180 may be made of a same material as the second sacrificial layer SF2. The connector 180 may have a thickness similar to that of the second sacrificial layer SF2. Similar thicknesses may include not only a case where the thicknesses are the same, but also a case where there is a difference in thicknesses, but a difference therebetween is within an error range. As will be described later, a portion of the second sacrificial layer SF2 may be etched to form the second portion 212 (see FIG. 1). Accordingly, the second portion 212 may have a similar thickness to that of the connector 180.

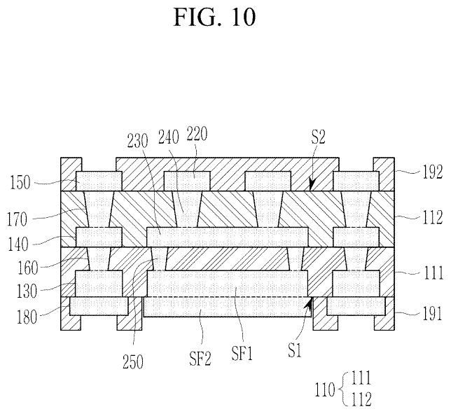

Referring to FIG. 10, a first solder resist layer 191 may be disposed on the first surface S1 of the insulating layer 110. The first solder resist layer 191 may be disposed on a surface of the first insulating layer 111. The first solder resist layer 191 may be formed to expose a portion of the connector 180. Additionally, a second solder resist layer 192 may be disposed on the second surface S2 of the insulating layer 110. The second solder resist layer 192 may be formed to expose a portion of the third circuit layer 150.

As a specific example, a photoresist may be provided on the first solder resist layer 191 to pattern the first solder resist layer 191. The first solder resist layer 191 may have an opening that exposes at least a portion of the connector 180 through exposure and development processes. For example, when the first solder resist layer 191 is a negative type, after the photoresist covers the opening area, the first solder resist layer 191 may be exposed, and the unexposed portion may be removed through development. Conversely, when the first solder resist layer 191 is a positive type, after the photoresist opens the opening area, the first solder resist layer 191 may be exposed, and the exposed portion may be removed by development.

In order to pattern the second solder resist layer 192, a photoresist may be provided on the second solder resist layer 192. The second solder resist layer 192 may have an opening that exposes at least a portion of the third circuit layer 150 through exposure and development processes. For example, when the second solder resist layer 192 is a negative type, after the photoresist covers the opening area, the second solder resist layer 192 may be exposed, and the unexposed portion may be removed through development. Conversely, when the second solder resist layer 192 is a positive type, after the photoresist opens the opening area, the second solder resist layer 192 may be exposed, and the exposed portion may be removed by development.

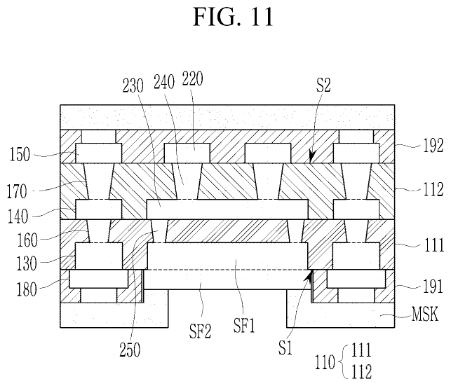

Referring to FIG. 11, a mask MSK may be formed in a remaining area excluding the etched area. The etched area may be an area corresponding to a portion of the first sacrificial layer SF1 and a portion of the second sacrificial layer SF2. The mask MSK may be an etching resist. The mask MSK may include a dry film.

Referring to FIG. 1, the second portion 212 may be formed by etching and removing a portion of the second sacrificial layer SF2. Then, the cavity 1110 and the first portion 211 may be formed by etching and removing a portion of the first sacrificial layer SF1.

The second sacrificial layer SF2 may have an edge area adjacent to the first insulating layer 111 and a central area surrounded by the edge area. Then, the second portion 212 may be formed by etching the central area of the second sacrificial layer SF2. The first sacrificial layer SF1 may have an edge area adjacent to the first insulating layer 111 and a central area surrounded by the edge area. Then, the first portion 211 may be formed by etching the central area of the first sacrificial layer SF1. The central area of the first sacrificial layer SF1 and the central area of the second sacrificial layer SF2 may overlap each other in the first direction.

The etching process may use dry etching or wet etching, but the present disclosure is not limited thereto. For example, the first sacrificial layer SF1 and the second sacrificial layer SF2 may be etched using an etchant. As a specific example, when the first sacrificial layer SF1 and the second sacrificial layer SF2 are formed of a same material, the first sacrificial layer SF1 and the second sacrificial layer SF2 may be removed together using a same etchant. As another example, when the first sacrificial layer SF1 and the second sacrificial layer SF2 are formed of different materials, the first sacrificial layer SF1 or the second sacrificial layer SF2 may be selectively removed using different etchants. Then, the mask layer MSK may be removed to form the circuit board 10 as shown in FIG. 1.

In accordance with a manufacturing method for a circuit board according to an embodiment, as the heat dissipating portion covering the side surface may be formed within the cavity where electronic components are accommodated, a space for mounting electronic components may be secured, and heat generated from electronic components may be efficiently absorbed and dispersed.

Hereinafter, an electronic component package according to an embodiment will be described with reference to FIG. 12. FIG. 12 illustrates a schematic cross-sectional view of an electronic component package according to an embodiment.

Referring to FIG. 12, the electronic component package 20 according to an embodiment may include the circuit board 10 according to the above-described embodiment. Hereinafter, a description of the first circuit board 10 may be applied in the same manner as the description of the circuit board 10 according to the above-described embodiment.

The electronic component package 20 according to an embodiment may include a first circuit board 10, a second circuit board 21, an electronic component 22, an encapsulant 23, a conductive member 24, an electrode 25, and an underfill 26. The second circuit board 21 may be connected to the first circuit board 10. The electronic component 22 may be mounted on a surface of the second circuit board 10. The electronic component 22 may be positioned in the cavity 1110. The encapsulant 23 may be positioned between the first and second circuit boards 10 and 21. The encapsulant 23 may be positioned to fill the cavity 1110. The encapsulant 23 may be positioned to cover at least a portion of the electronic component 22. The conductive member 24 may electrically connect the first circuit board 10 and the second circuit board 21. The electrode 25 may electrically connect the second circuit board 10 and the electronic component 22.

The second circuit board 21 may be a circuit board on which the electronic component 22 is mounted. As an example, the second circuit board 21 may include an insulating layer, a wire layer, a via layer, and a solder resist layer.

The electronic component 22 may be an integrated circuit (IC) die in which hundreds to millions of elements are integrated into a single chip. For example, the electronic component 22 may be a processor chip such as a central processor (e.g., CPU), a graphics processor (e.g., GPU), a field programmable gate array (FPGA), a digital signal processor, a cryptographic processor, a microprocessor, or a microcontroller, specifically an application processor (AP: Application Processor), but the present disclosure is not limited thereto. In addition, the electronic components 22 may be a memory such as other volatile memory (e.g., DRAM), a non-volatile memory (e.g., ROM), a flash memory, or a logic such as an analog-to-digital converter or an application-specific IC (ASIC). If necessary, the electronic component 22 may be a chip-type passive component, e.g., a chip-type capacitor such as a multi-layer ceramic capacitor (MLCC), a chip-type inductor such as a power inductor (PI), etc. The electronic component 22 may be covered by the encapsulant 23, and at least a first surface may be in physical contact with the encapsulant 23. The electronic component 22 may be surrounded by the first portion 211 and the second portion 212 of the heat dissipating portion 200.

The encapsulant 23 may cover a first surface of the first solder resist layer 191, a first surface of the second circuit board 21, and at least a portion of an outer surface of the electronic component 22. Additionally, the encapsulant 23 may fill at least a portion of the cavity 1110. As a result, the encapsulant 23 may cover at least a portion of an upper surface of the electronic component 22. For example, the encapsulant 23 may physically contact at least a portion of each of upper, lower, and side surfaces of the electronic component 22. The encapsulant 23 may have fluidity in a state before curing, so it may flow along the outer surface of the electronic component 22 and a surface of the first insulating layer 110 to fill the inside of the cavity 1110.

An insulating material may be used as a material for the encapsulant 23, and a thermosetting resin such as an epoxy resin or a thermoplastic resin such as polyimide may be used as the insulating material. Additionally, these resins containing inorganic fillers such as silica may be used. For example, an Ajinomoto build-up film (ABF) may be used as the material for the encapsulant 23. The ABF may be provided in the form of resin coated copper (ABF), but the present disclosure is not limited thereto. If necessary, photosensitive materials such as photo image-able dielectric (PIE) may be used. Additionally, the encapsulant 23 may be a known epoxy molding compound (EMC), but the present disclosure is not limited thereto.

The conductive member 24 may be positioned in at least a portion of an opening of the second circuit board 21. The conductive member 24 may physically and/or electrically connect the second circuit board 21 to the outside. For example, the conductive member 24 may electrically connect an exposed circuit pattern layer of the second circuit board 21 and the connector 180 of the first circuit board 10. Each conductive member 24 may be formed of tin (Sn) or an alloy containing tin (Sn), e.g., solder, etc., but the present disclosure is not limited thereto. For example, the conductive member 24 may be a ball, land, pin, or pillar-shaped metal post, or a pillar-shaped combination of a plurality of balls.

The underfill 26 may be a material filled between the electronic component 22 mounted on the second circuit board 21 and the second circuit board 21. The underfill 26 may secure the electronic component 22 within the cavity 1110. For example, the electrode 25 may protrude from the second circuit board 21, thereby creating a gap between a first surface of the electronic component 22 and the second circuit board 21. In this case, the underfill 26 may be filled in the gap between the electronic component 22 and the second circuit board 21.

In accordance with the electronic component package according to an embodiment, as the heat dissipating portion is positioned within the cavity of the first circuit board where the electronic components are accommodated, a space for mounting electronic components may be secured, and heat generated from electronic components may be efficiently absorbed and dispersed.

While this disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

What is claimed is:

1. A circuit board comprising:
an insulating layer including first and second surfaces opposing each other and having a cavity recessed from the first surface; and
a heat dissipating portion positioned in the cavity,
wherein the insulating layer includes an upper surface portion positioned in the cavity and facing the second surface, and a side surface portion surrounding the upper surface portion, and
the heat dissipating portion is positioned to cover the side surface portion, and extends from the upper surface portion to the second surface through the insulating layer.

2. The circuit board of claim 1, wherein
the heat dissipating portion extends from the upper surface portion to an outside of the cavity and includes an extension positioned on the side surface portion and the first surface, and
the extension includes a first portion positioned in the cavity to cover the side surface portion, and a second portion connected to the first portion and positioned to protrude from a reference surface parallel to the first surface.

3. The circuit board of claim 2, wherein
the heat dissipating portion further includes a first heat dissipation pattern positioned on the second surface.

4. The circuit board of claim 3, further comprising:
at least one circuit layer buried in the insulating layer, and
a first circuit layer connected to the at least one circuit layer and disposed around a first heat dissipation pattern on the second surface.

5. The circuit board of claim 3, wherein
the heat dissipating portion further includes a first heat dissipation via electrode that extends through at least a portion of the insulating layer and connects the first heat dissipation pattern and the first portion.

6. The circuit board of claim 5, wherein
the first heat dissipation via electrode is positioned in a stacking direction such that a center line thereof coincides with the first portion.

7. The circuit board of claim 6, wherein
the insulating layer includes a first insulating layer including the first surface on which the cavity is positioned, and a second insulating layer disposed on the first insulating layer and including the second surface on which the first heat dissipation pattern is positioned, and
the heat dissipating portion further includes a second heat dissipation pattern positioned on a surface of the first insulating layer opposing the first surface, and a second heat dissipation via electrode positioned to connect the first heat dissipation pattern and the second heat dissipation pattern through the second insulating layer.

8. The circuit board of claim 7, further comprising
a third insulating layer disposed between the first insulating layer and the second insulating layer.

9. The circuit board of claim 2, further comprising
a circuit layer buried from the first surface and disposed around the first portion,
wherein, in a thickness in a stacking direction, the first portion has a greater thickness than the circuit layer.

10. The circuit board of claim 2, wherein
the first portion and the second portion have different planar areas.

11. The circuit board of claim 10, wherein
the second portion has a larger planar area than the first portion.

12. The circuit board of claim 2, wherein
a portion of the second portion is positioned on the first portion, and a remaining portion of the second portion is positioned on the first insulating layer.

13. The circuit board of claim 2, wherein
the first portion extends along the side surface portion to surround the cavity.

14. The circuit board of claim 13, wherein
the second portion extends along an edge of the side surface portion.

15. An electronic component package comprising:
a first circuit board having a cavity on a surface;
a second circuit board connected to the first circuit board; and
an electronic component mounted on a surface of the second circuit board and positioned in the cavity,
wherein the first circuit board includes:
an insulating layer including first and second surfaces opposing each other and having the cavity recessed from the first surface; and
a heat dissipating portion positioned in the cavity,
wherein the insulating layer includes an upper surface portion positioned in the cavity and opposing the second surface, and a side surface portion surrounding the upper surface portion, and
the heat dissipating portion is positioned to cover the side surface portion, and extends from the upper surface portion to the second surface through the insulating layer.

16. The electronic component package of claim 15, wherein
the heat dissipating portion includes an extension extending from the upper surface portion to an outside of the cavity and positioned on the side surface portion and the first surface, and
the extension includes a first portion positioned in the cavity to cover the side surface portion, and a second portion connected to the first portion and positioned to protrude from a reference surface parallel to the first surface.

17. The electronic component package of claim 16, wherein
the heat dissipation portion further includes a first heat dissipation pattern positioned on the second surface, and a first heat dissipation via electrode extending through at least a portion of the insulating layer and positioned to connect the first heat dissipation pattern and the first portion.

18. The electronic component package of claim 16, wherein
the first portion and the second portion are positioned to surround the electronic component.

19. A manufacturing method for a circuit board, comprising:
forming a circuit layer and a first sacrificial layer;
forming a first insulating layer to bury the circuit layer and the first sacrificial layer;
forming a first heat dissipation via electrode to extend through the first insulating layer to be connected to an edge area of the first sacrificial layer;
forming a first heat dissipation pattern on a surface of the first insulating layer to be connected to the first heat dissipation via electrode;
forming a connector on another surface of the first insulating layer to be connected to the circuit layer;
forming a second sacrificial layer on the first sacrificial layer; and
forming a heat dissipating portion by etching a central area of the first sacrificial layer and a central area of the second sacrificial layer.

20. The manufacturing method of claim 19, wherein
the forming of the second sacrificial layer includes forming the second sacrificial layer by forming a portion thereof on the first sacrificial layer and a remaining portion on the another surface of the first insulating layer.
